(19) United States
(12) Patent Application Publication
(10) Pub. No.: US 2009/0128939 A1
(43) Pub. Date: May 21, 2009

(54) Durability broad band metallic neutral density optical filters and related methods of manufacture

(75) Inventor: Jamie Knapp, Mendon, MA (US)

Correspondence Address: NEWPORT CORPORATION, 1791 DEERE AVENUE, IRVINE, CA, 92606, US

(73) Assignee: Newport Corporation, Irvine, CA (US)

(21) Appl. No.: 12/288,868

(22) Filed: Oct. 23, 2008

Related U.S. Application Data
(60) Provisional application No. 61/001,425, filed on Oct. 31, 2007.

(51) Int. Cl. G02B 5/20; C23C 14/08

(52) U.S. Cl. 359/888; 427/527

(57) ABSTRACT

The present application disclosed various embodiments of improved durability broad band metallic neutral density optical filters and various methods for the manufacture thereof. The devices disclosed herein include a fully densified protective thin-film layer that is essentially 100% bulk devices, free of substantially all porosity, thereby providing full environmental protection of the underlying sensitive metallic filter layer and substrate. In one embodiment, the present application is directed to a neutral density filter and includes a substrate, at least one metallic filter layer having a thickness from about 10 nm to about 100 nm applied to the substrate, and at least one protective layer having a thickness of about 10 nm to about 100 nm applied to the filter layer using an ion-plating process.

### CROSS REFERENCE TO RELATED APPLICATIONS

The present application claims priority to U.S. Provisional Patent Application Ser. No. 61/001,425, filed Oct. 31, 2007, the entire contents of which are hereby incorporated by reference in its entirety herein

### BACKGROUND

Many optical applications require the controlled attenuation of an incident beam of light evenly over a broad spectral range. Generally, this attenuation can be accomplished by either optical absorption or a combination of absorption and reflection. One device which is presently available for achieving the desired attenuation is a neutral density filter. One class of neutral density filters which is presently available employs absorption as the primary means to attenuate incident light. Typically, these filters consist of absorptive grey glasses, such as NG-type glasses produced by the Schott Corporation. While these devices have proven somewhat useful in the past, a number of shortcomings have been identified. For example, NG-type glasses must be carefully polished to a carefully controlled thickness in order to achieve its desired level of attenuation. Further, melt-to-melt variations of these glasses greatly complicates the repeatability of such attenuation level. As such, maintaining the desired optical attenuating precision between devices incorporating NG-type glasses has been difficult if not impossible to achieve.

In response thereto, alternate neutral density filters have been developed. For example, as shown in FIG. 1, a current state-of-the-art optically attenuating filter 1 consists of a transparent substrate 2 (such as 1 mm thick synthetic fused silica or borofloat glass) over-coated with a metallic thin film 3 (of thicknesses ranging from a few nm to a few thousand nm). By finely controlling the physical thickness of this metal film (e.g. inconel, NiCr, etc.), the desired attenuation level is achieved. Generally, these types of attenuating filters offer a much broader range of spectral neutrality (typically from 250 nm to 2500 nm when using the fused silica substrate) as compared with NG-type filters. Such metallic films are traditionally deposited by Physical Vapor Deposition techniques (e.g. thermal evaporation under vacuum). Typically, the optical density range of such metal-based attenuation filters is from 0.1 OD (79.4%) to 4.0 OD (0.01%). While these devices have addressed many of the drawbacks associated with NG-type devices, a number of shortcomings have been identified. For example, as shown in FIG. 2, a significant drawback of such metal-thin-film based optical attenuating filters is their poor resistance to incident high-energy light exposure, particularly in the ultraviolet range (wavelengths <400 nm). The exposed metallic films may decompose due to surface oxidation, resulting in a rapid deterioration in their optical properties. A need, therefore, presently exists for such broad-band attenuation filters, but with a significant improvement in its physical durability and field-life then presently available.

In light of the foregoing, various methods have been developed to enhance the durability of metallic thin film attenuating filters. For example, one common method to help extend the field longevity of such metal-based optical attenuation filters is to imbed the environmentally sensitive metal film within an optical epoxy. As shown in FIG. 3, these filters 4 include a substrate 5 having a metallic layer 6 applied thereto. Further an adhesive or epoxy layer 7 is applied to the filter layer 6. Thereafter, a protective device 8 is affixed to the adhesive layer 7. Although offering some environmental protection (the epoxy behaves as a hermetic “seal”), such an optical epoxy limits the product's exposure temperature to about <125° C. At temperatures greater than about 125° C. the optical epoxy softens and degrades. In addition, these protective epoxies severely solarize when exposed to ultraviolet light. More specifically, UV exposure may photo-chemically deteriorate the organic epoxy causing it to become optically opaque. Such epoxy-protected neutral density filters are therefore useful for very low power UV applications (wavelengths <400 nm), or for only moderate incident powers in the visible spectrum (>400 nm). In the alternative, metal based neutral density filters may be overcoated with a dielectric film, such as silica (SiO2). Current overcoating methods involve various deposition processes such as electron beam deposition, ion assisted deposition, CVD, magnetron and/or ion beam sputtering, and the like. To preserve the required spectral broad-band performance required for these neutral density filters, such protective dielectric overcoat films must be very thin. For example, the protective overcoating film may have a thickness of about 50 nm or less. Unfortunately, the microstructure of such very thin current-art protective films are “columnar” i.e., have a porous morphology, allowing atmospheric moisture and air to eventually absorb through the film and deteriorate the underlying metallic neutral density film.

In light of the foregoing, there is ongoing need for a neutral density filter offering critical spectral broad-band optical performance desired (250 nm-2500 nm) while having superior durability and longevity compared to presently available devices.

### SUMMARY

The present application disclosed various embodiments of improved durability broad band metallic neutral density optical filters and various methods for the manufacture thereof. Unlike prior art devices, the devices disclosed herein include a fully densified protective thin-film layer that is essentially 100% bulk (i.e. free of substantially all porosity), thereby providing full environmental protection of the underlying sensitive metallic filter layer and substrate.

In one embodiment, the present application is directed to a neutral density filter and includes a substrate, at least one metallic filter layer having a thickness from about 10 nm to about 100 nm applied to the substrate, and at least one protective layer having a thickness of about 10 nm to about 100 nm applied to the filter layer using an ion-plating process.

In another embodiment, the present application is directed to a neutral density filter and includes a substrate, at least one metallic filter layer having a thickness from 45 nm to about 65 nm applied to the substrate, and at least one protective layer having a thickness less than about 50 nm applied to the filter layer using an ion-plating process.

In another embodiment, the present application is directed to a method of manufacturing a neutral density filter and includes providing a substrate, depositing at least one metallic filter layer on the substrate, applying at least one protective layer of silicon dioxide having a thickness of about 50 nm or less to the metallic filter layer coated substrate using an ion plating process.

Other features and advantages of the embodiments of the of improved durability broad band metallic neutral density optical filters as disclosed herein will become apparent from a consideration of the following detailed description.

### BRIEF DESCRIPTION OF THE DRAWINGS

Various improved durability broad band metallic neutral density optical filters will be explained in more detail by way of the accompanying drawings, wherein

FIG. 1 shows a perspective view of a prior art metallic neutral density filter having a substrate overcoated with a metallic thin film;

FIG. 2 shows graphically the wavelength related transmittance of prior art metallic neutral density filters having a poor resistance to incident high-energy light exposure, particularly in the ultraviolet range;

FIG. 3 shows a perspective view of another embodiment of a prior art metallic neutral density filter having a substrate with a metallic layer applied thereto, an adhesive or epoxy layer, and a protective device positioned on the epoxy layer;

FIG. 4 shows a cross-sectional view of an embodiment of a coating apparatus which may be used to manufacture novel broad metallic neutral density filters;

FIG. 5 shows a perspective view of an embodiment of a novel broad band metallic neutral density filter; and

FIG. 6 shows graphically the performance characteristics of the novel broad band metallic neutral density filter.

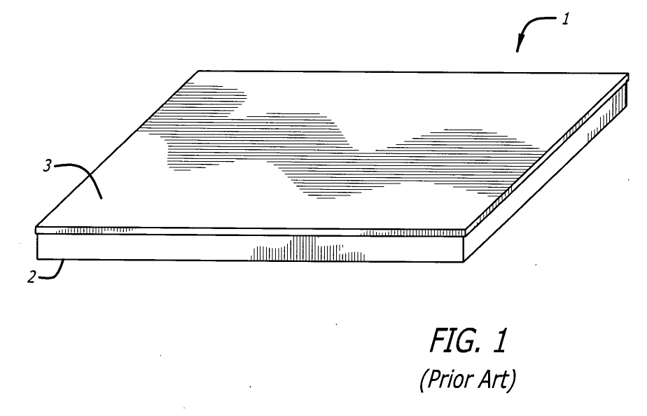

### DETAILED DESCRIPTION

FIG. 4 illustrates an embodiment of a coating apparatus which may be used to manufacture broad band metallic neutral density filters offering improved durability. In the illustrated embodiment, the coating apparatus 10 comprises an ion plating system as described in U.S. Pat. No. 6,139,968, the entirely of which is incorporated by reference herein. As shown in FIG. 4, the coating apparatus 10 includes an evacuatable coating vessel 12 and an evacuation device 14 in fluid communication with the vessel 12. As such, the evacuation device 14 is configured to remove fluid from and/or provide fluid to the vessel 12. At least one deposition plasma source 16 and one or more electron beam guns 18 configured to supply electrons of energy directed towards one or more containment structures 20, 20′ are positioned within the vessel 12. In the illustrated embodiment, two 270° electron beam guns are positioned within the vessel 12, although those skilled in the art will appreciate that any number or type of electron beam guns may be used. The deposition plasma source 16 may include a heated tantalum filament or other heating device and a gas inlet 17.

As shown in FIG. 4, two containment structures 20, 20′ are positioned within the vessel 12. In one embodiment the containment structures 20, 20′ may comprise an electrically conductive structure 20, 20′ that may be coupled to the plasma source 16 via at least one low voltage, high current power supply 17′. Those skilled in the art will appreciate that any number of containment vessels may be positioned within the vessel 12. The number of containment structures 20, 20′ within the vessel 12 may vary depending on the composition of the coating layer(s) to be produced by the apparatus 10. For example, the first crucible 20 holds a first source material while the second crucible 20′ holds a second source material. The first and second coating materials may be the same or different materials. As such, the separate source chemicals will be separately activated by one or more electron guns 18.

Further, the containment vessels 20, 20′ may be constructed from any variety and combination of materials, including, without limitation, copper, molybdenum, stainless steel, aluminum, gold, silver, titanium, various metals, glass, ceramics, composite materials, polymers, and the like. For example, in one embodiment at least one of the containment vessels 20, 20′ is constructed of copper and includes a molybdenum liner. The containment structures 20, 20′ are configured to receive on or more coating materials 22 and 22′. Exemplary coating materials 22, 22′ include, without limitation, various metallic oxides, silicon dioxide (SiO₂), aluminum oxide (Al₂O₅), Hafnium Oxide (HfO₂), Tantulum Pentoxide (Ta₂O₅), silicon, titanium, aluminum, tantalum, hafnium, zirconium, and/or other protective overcoats, and the like. An exemplary suitable coating apparatus 10 is the BAP 800 Batch Ion Plating System, which is commercially available from Balzers Aktiengesellschaft of Liechtenstein, although any variety of systems may be used.

Referring again to FIG. 4, the coating apparatus 10 further includes at least one substrate support structure 24 positioned within the vessel 12. In the illustrated embodiment, the substrate support structure 24 is positioned opposite the containment structures 20, 20′ and configured to support one or more substrates 26 onto which the coating materials 22, 22′ are to be deposited/applied as coating layers. Optionally, the substrate support structure 24 may be formed in any variety of shapes and/or configurations, including, without limitation, an electrically isolated substrate support structure, a rotatable substrate support structure, a dome-shaped structure, and the like. Further, substrate support structure 24 may be coupled to any surface of the vessel 12.

Any number and variety of substrates 26 may be positioned within the vessel 12 and coated. Exemplary substrates 26 include, without limitation, silica-based substrates, fused silica substrates, glass substrates, composite optical substrates, metal substrates, plastic substrates, semiconductor substrates, and electronic device substrates, substrates manufactured from crown glass, soda-lime float glass, natural quartz, synthetic fused silica, Schott BK-7, and the like.

As shown in FIG. 4, one or more feedlines 30 may be in fluid communication with the vessel 12 and configured to provide one or more fluids thereto. Exemplary fluids include, without limitation, oxygen, reactive gases, and the like. In one embodiment, the reactive gases may be introduced into the vessel 12 through the feedlines 30 during deposition process. Further, one or more plasma sources 32 may be positioned within the vessel 12.

During use, the coating vessel 12 is evacuated by vacuum system 14 to provide a base vacuum pressure to the coating vessel 12 of less than about 3×10-6 mbar. The evacuation device 14 may comprise any number or variety of evacuation devices, including, without limitation, vacuum pumps, oil diffusion pumps, Roots Blowers, and the like. Thereafter, one or more electron beam guns 18 direct one or more intense electron beams into the containment structure(s) 20, 20′, thereby vaporizing at least one of the coating material(s) 22 and 22′ contained therein. In one embodiment, multiple coating materials 22, 22′ may be applied to the substrates 26 sequentially. In another embodiment, multiple coating materials 22, 22′ are applied to the substrates 26 simultaneously.

The substrates 26 positioned on the substrate support structure 24 become negatively biased due to the deposition plasma discharge during the coating process. As a result, the vaporized coating material(s) (denoted by M+ in FIG. 4) activated by the deposition plasma becomes highly energetic, ionized and chemically reactive. The energized material M+ is attracted to the one or more substrates 26 via electromagnetic coulomb attraction, after which coating/film deposition occurs. In one embodiment, the deposition plasma procedure may be commenced immediately after the gas plasma pretreatment is completed, without vacuum interruption. In an alternate embodiment, an interruption of the vacuum may be introduced.

Unlike other coating processes known in the art, one or more metallic coatings layers may be applied to the substrate 26 at about room temperature. As such, the substrates 26 need not be heated to a temperature greater than room temperature. Optionally, the substrates 26 may be heated to a temperature greater than room temperature if desired. For example, in one embodiment, the substrates 26 may be heated to a temperature greater than about room temperature but less than about 125° C. Further, the coating apparatus 10 may further include one or more additional auxiliary devices (e.g., auxiliary coils for the production of magnetic fields, etc.), which are generally known in the art.

One or more reactive gases may be introduced into the vessel 12 prior to, during, or following the deposition process via one or more feedlines 30. For example, the feedlines 30 may be configured to discharge one or more reactive gases at a position proximate to the containment structures 20, 20′, thereby permitting the effective density of reactive gas to mix and react with material vaporized from the containment structure(s) 22, 22′ during the ion plating coating process. Any variety of reactive gases may be used, including, without limitation, oxygen, nitrogen, aliphatic and aromatic hydrocarbons (e.g., acetylene, methane, ethane, propylene, benzene, etc.) and/or similar reactive gases. For example, when depositing a coating that is comprised of silicon oxide, silicon dioxide, aluminum oxide and/or other oxygen-containing layers, oxygen may be supplied through one or more feedlines 30 to react with the one or more source chemicals/metals that are vaporized from containment structure 20 and/or 20′. Optionally, a mixture of one or more reactive gases may be introduced into coating vessel 12 to produce a coating layer of a desired composition onto the one or more substrate(s) 26. For example, nitrogen and acetylene may be simultaneously supplied through separate lines 30 to provide a carbonitride-type coating on the substrate(s) 26. Coating layers having other compositions also may be applied, as will be appreciated by those of ordinary skill in the art.

Table 1 below present one, non-limiting example of settings for the coating apparatus described above used to produce a neutral density filter.

TABLE 1

| Coating | Crucible | E-beam | | Deposition | | | |
|---|---|---|---|---|---|---|---|
| Material | material | high voltage | Emission | Rate | Ramp 1 | Ramp 2 | Ramp 3 |
| Silicon | Copper | 10 kV | 400 mA | 0.4 nm/s | 20 s/38% | 40 s/46% | 40 s/51% |
| Dioxide | | | | | | | |

| | | | | Anode-to | | |
|---|---|---|---|---|---|---|
| Coating | Hold | Arc | Arc | Ground | | |
| Material | Power | Current | Voltage | Voltage | Plasma Gas | Reaction Gas |
| Silicon | 22.0% | 75 A | 55 V | 37 V | Argon at 2.8 mbar | Oxygen at 1.2 × 10⁻³ mbar |
| Dioxide | | | | | within plasma | within coating vessel |

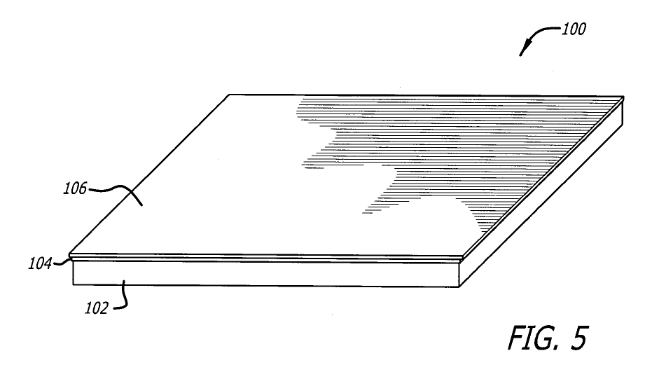

FIG. 5 shows an embodiment of a neutral density filter manufactured using the methods described above. As shown in FIG. 5, the novel neutral density filter 100 includes a substrate 102 having at least one filter layer 104 applied thereto. In one embodiment, the substrate 102 may comprise a silica substrate. Optionally, the substrate 102 may be manufactured from any variety of materials, including, without limitation, sapphire, fused silica, soda-lime glass, borosilicates, optical glass, composite materials, and optically transparent polymers. Further, the substrate 102 may be manufactured in any variety of thickness, or other transverse dimensions. For example, the substrate 102 may have a thickness from about 0.1 mm to about 100 mm. More specifically, the substrate 102 may have a thickness from about 0.5 mm to about 5 mm. In another embodiment, the substrate 102 has a thickness from about 0.75 mm to about 1.25 mm.

Referring again to FIG. 5, any variety of materials may be used to form the metallic neutral density layer 104. For example, on one embodiment the metallic layer 104 comprises one or more layers of Nickel-Chromium (NiCr) applied to the substrate 102. Alternate filter layer materials include, without limitation, Aluminum, Silver, Copper, Inconel, and Chrome. As such, the metallic neutral density layer 104 may be formed on the substrate 102 using any number of coating techniques known in the art, including, without limitation, thermal evaporation, electron-beam deposition, sputtering, and CVD. Further, any variety of thicknesses of the metallic layer material may be applied to the substrate 102. In one embodiment, the filter layer 104 has a thickness of about 55 nm. Those skilled in the art will appreciate that the filter layer 104 may have a thickness from about 0.01 nm to about 100 μm. In an alternate embodiment, the filter layer 104 has a thickness from about 10 nm to about 100 nm. In a more specific embodiment, the filter layer 104 has a thickness from about 30 nm to about 70 nm. In another embodiment, the filter layer 104 has a thickness from about 45 nm to about 65 nm.

As shown in FIG. 5, at least one protective layer 106 may be applied to the substrate 102, the filter layer 104, or both. For example, in the illustrated embodiment, the protective layer 106 is applied to the filter layer 104. Optionally, the protective layer 106 may be applied to the substrate 102. The protective layer 106 may comprise any variety of materials. For example, in the illustrate embodiment, the protective layer 106 comprises a single-layer of densified, non-porous stabilized amorphous silicon dioxide (SiO2). In an alternate embodiment, the protective layer 106 may comprise oxides of aluminum, hafnium, or tantalum. Any variety of thicknesses of protective materials may be used to form the protective layer 106. For example, protective layer 106 may have a thickness from about 10 nm to about 50 μm. In an alternate embodiment, the protective layer 106 has a thickness from about 10 nm to about 100 nm. In another embodiment, the protective layer 106 has a thickness from about 15 nm to about 65 nm. In one embodiment, the protective layer 106 has an optimized thickness of about 50 nm or less. The protective layer 106 may be applied to the substrate 102, filter layer 104, or both using any variety of deposition techniques. In one embodiment, the protective layer 106 is applied using an ion-plating process. For example, a substrate 102 having a filter layer 104 deposited thereon may be positioned within the coating apparatus 10 described above (See FIG. 4). Thereafter, Silicon Dioxide is positioned within at least one crucible 22, 22′ and deposited onto the coated substrate 102 using the ion-plating technique described above and outline in Table 1. Unlike other current-art deposition processes, this unique fully densified protective thin-film coating is essentially 100% bulk (free of all porosity), thereby providing full environmental protection of the underlying sensitive metallic ND layer. Further, the protective layer 106 is essentially optically transparent in the required UV to IR wavelengths (250 nm-2500 nm).

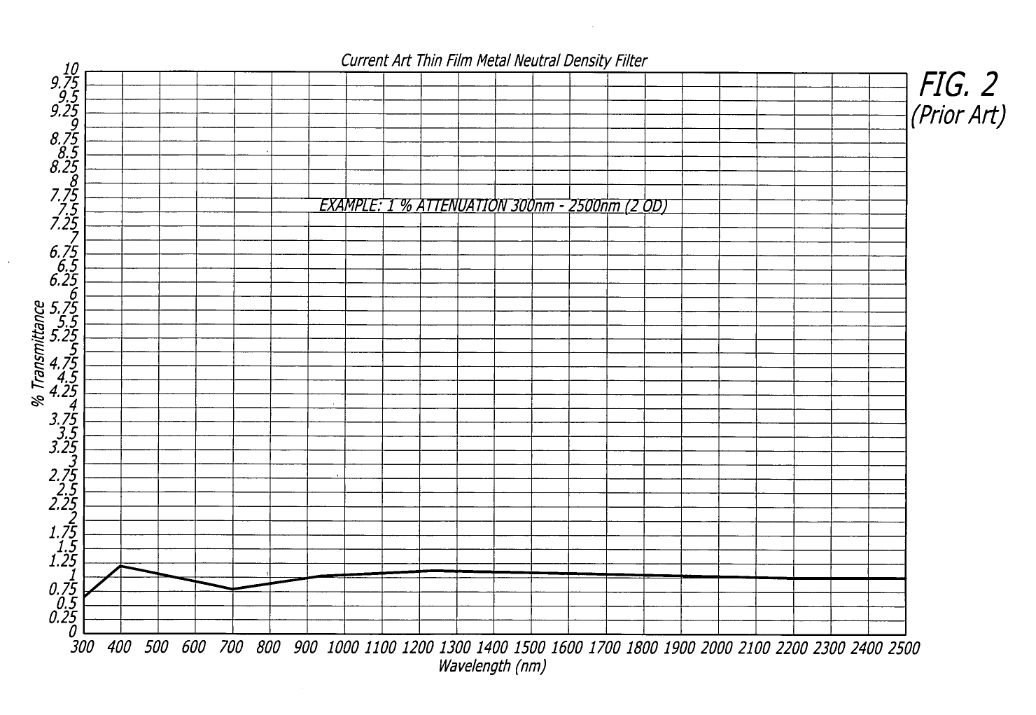

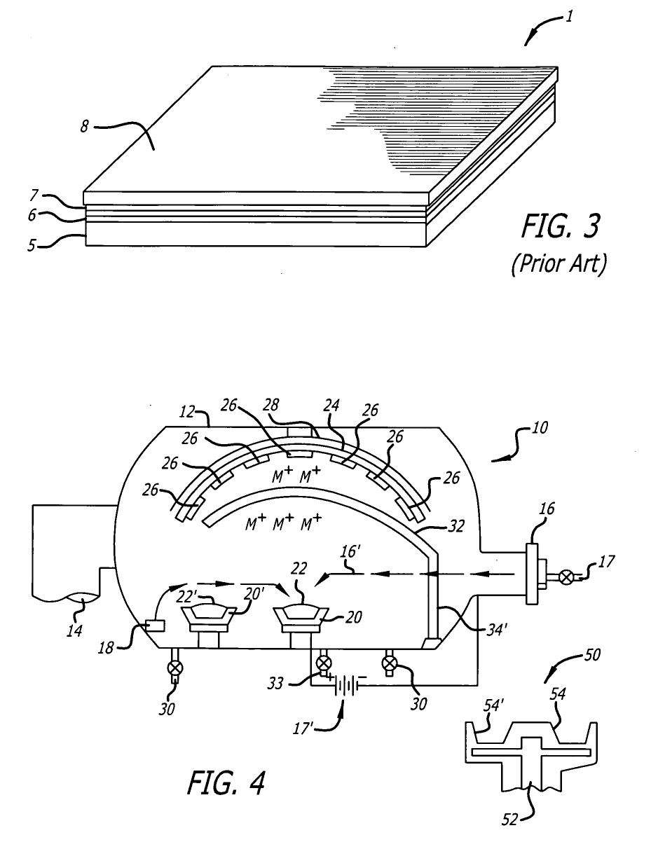

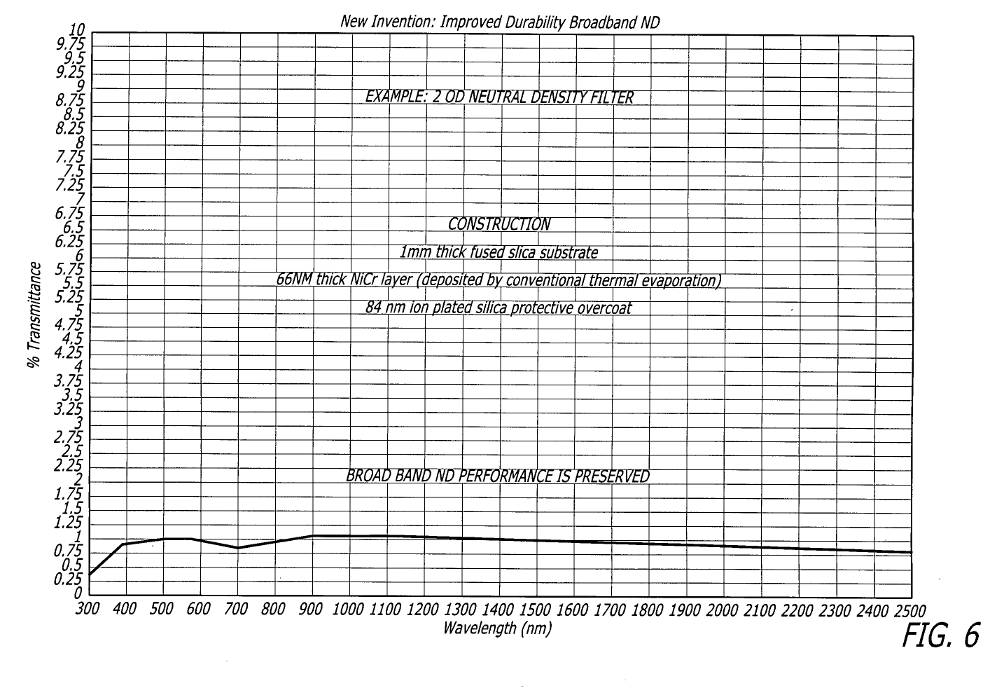

FIG. 6 shows graphically the performance characteristics of the neutral density filter shown in FIG. 5. As shown, the broad-band spectral performance of this filter is maintained, in contrast to the broad-band spectral performance of existing neutral density filters (see FIG. 2). Since the unique densified silica encapsulation is fully non-porous, the occurrence of any metal oxidation due to intense UV and/or intense incident light energy exposure is greatly reduced if not eliminated. This cost-effective approach therefore succeeds in creating the ideal spectral broad-band attenuating performance along with the desired permanent damage-resistant features needed for so many critical applications.

The various embodiments disclosed herein are illustrative of the principles of the invention. Other modifications may be employed which are within the scope of the invention. Accordingly, the devices disclosed in the present application are not limited to that precisely as shown and described herein.

What is claimed is:

1. A neutral density filter, comprising:
a substrate;
at least one metallic filter layer having a thickness from about 10 nm to about 100 nm applied to the substrate; and
at least one protective layer having a thickness of about 10 nm to about 100 nm applied to the filter layer using an ion-plating process.

2. The device of claim 1 wherein the substrate is constructed from at least one material selected from the group consisting of sapphire, silica, fused silica, soda-lime glass, borosilicates, optical glass, composite materials, and optically transparent polymers.

3. The device of claim 1 wherein the substrate has a thickness of about 0.1 mm to about 100 mm.

4. The device of claim 1 wherein the substrate has a thickness of about 0.75 mm to about 1.25 mm.

5. The device of claim 1 wherein the filter layer is constructed of at least one material selected from the group consisting of Nickel-Chromium, Aluminum, Silver, Copper, Inconel, and Chrome.

6. The device of claim 1 wherein the filter layer has a thickness of about 30 nm to about 70 nm.

7. The device of claim 1 wherein the filter layer has a thickness about 45 nm to about 65 nm.

8. The device of claim 1 wherein the protective layer is constructed of at least one material selected from the group consisting of non-porous stabilized amorphous Silicon Dioxide, Aluminum Dioxide, Hafnium Dioxide, and Tantalum Dioxide.

9. The device of claim 1 wherein the protective layer has a thickness of about 10 nm to about 100 nm.

10. The device of claim 1 wherein the protective layer has a thickness of about 50 nm or less.

11. The device of claim 1 wherein the protective layer protective layer 106 is optically transparent at wavelengths from about 250 nm to about 2500 nm.

12. A neutral density filter, comprising:
a substrate;
at least one metallic filter layer having a thickness from 45 nm to about 65 nm applied to the substrate; and
at least one protective layer having a thickness less than about 50 nm applied to the filter layer using an ion-plating process.

13. The device of claim 12 wherein the substrate is constructed from at least one material selected from the group consisting of sapphire, silica, fused silica, soda-lime glass, borosilicates, optical glass, composite materials, and optically transparent polymers.

14. The device of claim 12 wherein the filter layer is constructed of at least one material selected from the group consisting of Nickel-Chromium, Aluminum, Silver, Copper, Inconel, and Chrome.

15. The device of claim 12 wherein the protective layer is constructed of at least one material selected from the group consisting of non-porous stabilized amorphous Silicon Dioxide, Aluminum Dioxide, Hafnium Dioxide, and Tantalum Dioxide.

16. The device of claim 12 wherein the neutral density filter comprises a silica substrate, a filter layer manufactured from Nickel-Chromium and having a thickness of about 50 nm to about 60 nm, and a protective layer manufactured from non-porous stabilized amorphous Silicon Dioxide having a thickness of less than about 50 nm.

17. A method of manufacturing a neutral density filter, comprising:
providing a substrate;
depositing at least one metallic filter layer on the substrate;
applying at least one protective layer of silicon dioxide having a thickness of about 50 nm or less to the metallic filter layer coated substrate using an ion plating process.

18. The method of claim 17 further comprising depositing a metallic filter layer having a thickness of about 30 nm to about 70 nm.
